(19) United States
(12) Patent Application Publication
(10) Pub. No.: US 2025/0096847 A1
(43) Pub. Date: Mar. 20, 2025

(54) CONTACTLESS COMMUNICATION DEVICE BY ACTIVE LOAD MODULATION

(71) Applicant: STMicroelectronics International N.V., Geneva (CH)

(72) Inventors: Florent BARTHELEMY, Grenoble (FR); Marc HOUDEBINE, Crolles (FR); Laurent Jean GARCIA, Le Champ Pres Froges (FR)

(73) Assignee: STMicroelectronics International N.V., Geneva (CH)

(21) Appl. No.: 18/882,469

(22) Filed: Sep. 11, 2024

(30) Foreign Application Priority Data
Sep. 19, 2023 (FR) 2309886

(51) Int. Cl. H04B 5/48; H03L 7/08; H04B 5/77

(52) U.S. Cl. CPC H04B 5/48; H04B 5/77; H03L 7/08

(57) ABSTRACT

A device of contactless communication by active load modulation includes a clock signal extraction circuit configured to receive as an input a reception signal and to output a clock signal having a first value when the reception signal is greater than a threshold of the clock signal extraction circuit and having a second value when the reception signal is smaller than the threshold. The device includes a circuit for modifying the value of the threshold, configured to decrease the value of the threshold when the value of the clock signal is equal to the first value, or to increase the value of the threshold when the value of the clock signal is equal to the second value.

### CROSS-REFERENCE TO RELATED APPLICATION(S)

This application is a translation of and claims the priority benefit of French patent application number 2309886, filed on Sep. 19, 2023, entitled “Dispositif de communication sans contact par modulation active de charge doté d'un circuit d'extraction de signal d'horloge à seuil dynamique,” which is hereby incorporated by reference to the maximum extent allowable by law.

### BACKGROUND

### Technical Field

The present disclosure generally concerns the field of wireless communications between a reader and a device of contactless communication by active load modulation, in particular between a reader and such a device in card emulation (or CE) mode. The present disclosure may in particular concern the field of contactless communications implemented in NFC (“Near Field Communication”) technology.

### Description of the Related Art

Near-field communication, or NFC, is a wireless connectivity technology allowing a communication over a short distance, for example in the order of some ten centimeters, between electronic devices, such as for example a contactless chip card and a reader, or a CE device (for example a cell phone or a connected object) and a reader.

A contactless communication device is a device capable of exchanging information via an antenna with another contactless device, for example a reader, according to a contactless communication protocol.

A NFC device, which is a contactless device, is a device compatible with the NFC technology. The NFC technology is an open technological platform standardized in the ISO/IEC 18092 and ISO/IEC 21481 standard but incorporates many already-existing standards such as for example the type-A and type-B protocols defined in the ISO-14443 standard, which may be communication protocols usable in the NFC technology.

A CE device may be used to exchange information with another contactless device, for example a contactless reader, by using a contactless communication protocol usable in the NFC technology.

During the transmission of information between a reader and a CE device or a NFC card, the reader generates an electromagnetic field via its antenna which is generally, according to the standards conventionally used, a sine wave having a frequency equal to 13.56 MHz. Each of the NFC devices (reader and CE device) transmits data by using a modulation scheme, for example an amplitude shift keying or ASK or OOK (“On Off Keying”) modulation.

Two operating modes are possible: a passive mode, which corresponds to the mode used by a NFC card, or an active mode, which generally corresponds to the mode used by a CE device.

In a passive mode, also called PLM or passive load modulation, only the reader generates the electromagnetic field and the card is then passive. The antenna of the card modulates the electromagnetic field generated by the reader via a modification of a load connected across the antenna of the card, which modifies the output impedance of the reader antenna due to the magnetic coupling between the two antennas. This results in a change in the amplitudes and/or the phases of the voltages and currents present at the antennas of the reader and of the card. The information is thus transmitted from the card to the reader by load modulation to the antenna currents of the reader.

In the active mode, also called ALM or active load modulation, the reader and the CE device both generate an electromagnetic field. This operating mode is used when the CE device is provided with a specific power source, for example a battery.

Generally, a CE device comprises an antenna smaller than that of a NFC card, and this is the reason why an active load modulation is often used in such a device.

During an active load modulation, the electromagnetic fields emitted by the reader and the CE device are in phase with each other so that the detection sensitivity of the device is not decreased. The CE device may in particular include a phase-locked loop, or PLL, and a transmission circuit having its output electrically coupled to the antenna.

The CE device may be configured to extract a clock signal from the electromagnetic field emitted by the reader and lock the PLL on the rising or falling edges of this signal. This clock signal extraction is for example performed by a differential comparator electrically coupled to the output of the passive network of the antenna of the CE device and including for example a high-gain amplifier operating in saturation. The output signal of the PLL can then be used to implement a digital conversion enabling to decode the modulation signal of the reader.

So that the CE device can answer the reader, the response signal of the CE device has to be in phase with the electromagnetic field emitted by the reader. The clock signal extracted from the electromagnetic field emitted by the reader thus has to follow the phase and the frequency of the electromagnetic field emitted by the reader, and must include no parasitic variations.

In the case of an OOK-type modulation, the electromagnetic field including the modulation signal alternates between a high state and a low state. Noise may however be present in the electromagnetic field received in the CE device when the modulation signal is in the low state, due to the coupling existing between the reader and the CE device. The clock signal extracted from this field may in this case include parasitic variations, or jitter, likely to generate phase shifts and errors in the obtained output signal.

### BRIEF SUMMARY

An embodiment overcomes all or part of the disadvantages of known solutions and provides a device of contactless communication by active load modulation, including at least:
a clock signal extraction circuit configured to receive as an input a reception signal and to output a clock signal having a first value when the reception signal is greater than a threshold of the clock signal extraction circuit and having a second value when the reception signal is smaller than the threshold; and
a circuit for modifying the value of the threshold, configured to decrease the value of the threshold when the value of the clock signal is equal to the first value, or to increase the value of the threshold when the value of the clock signal is equal to the second value.

According to a specific embodiment, the threshold of the clock signal extraction circuit has a zero value.

According to a specific embodiment, the clock signal extraction circuit and the circuit for modifying the value of the threshold are configured such that the decreased value of the threshold is in the range from 10% to 20% of a minimum amplitude of the reception signal.

According to a specific embodiment, the clock signal extraction circuit includes a differential pair.

According to a specific embodiment, the clock signal extraction circuit further includes a first current mirror electrically coupled in parallel with the differential pair.

According to a specific embodiment, the circuit for modifying the value of the threshold is configured to unbalance a biasing of the first current mirror of the clock signal extraction circuit or a biasing of the differential pair and of the first current mirror of the clock signal extraction circuit.

According to a specific embodiment, the clock signal extraction circuit further includes an amplifier having an input electrically coupled to one of the branches of the first current mirror.

According to a specific embodiment, the circuit for modifying the value of the threshold includes a second current mirror electrically coupled to one of the branches of the first current mirror and switches configured to electrically couple the second current mirror to an electric power supply potential of the device and to a current source, itself coupled to a reference electric potential of the device, according to the value of the clock signal.

According to a specific embodiment, the circuit for modifying the value of the threshold includes a transistor and a switch configured to electrically couple the transistor of the circuit for modifying the value of the threshold in parallel with a transistor of the differential pair when the value of the clock signal is equal to the first value or to the second value.

According to a specific embodiment, the device further includes a phase-locked loop having an input electrically coupled to an output of the clock signal extraction circuit.

According to a specific embodiment, the device may further comprise:
a digital conversion circuit including an input electrically coupled to an output of the phase-locked loop;
a transmission circuit including an output electrically coupled to the antenna and on which a modulation signal in phase with the reception signal is intended to be delivered, and including a first input electrically coupled to an output of the phase-locked loop and a second input electrically coupled to an output of the digital conversion circuit.

In one embodiment, a method includes receiving a reception signal at a clock signal extraction circuit and outputting, from the clock signal extraction circuit, a clock signal having a first value when the reception signal is greater than a threshold of the clock signal extraction circuit and having a second value when the reception signal is smaller than the threshold. The method includes modifying, with a circuit, the threshold by decreasing the threshold when the value of the clock signal is equal to the first value and increasing the threshold when the value of the clock signal is equal to the second value.

In one embodiment, a device includes a clock extraction circuit. The clock extraction circuit includes a differential input coupled to receive a reception signal from the matching circuit, a feedback input, and an output configured to provide a clock signal based on the reception signal and an internal threshold. The device includes a feedback circuit having an input coupled to receive the clock signal and an output coupled to the feedback input of the clock extraction circuit.

### BRIEF DESCRIPTION OF THE SEVERAL VIEWS OF THE DRAWINGS

The foregoing features and advantages, as well as others, will be described in detail in the rest of the disclosure of specific embodiments given by way of illustration and not limitation with reference to the accompanying drawings, in which:

FIG. 1 schematically shows an example of a device of contactless communication by active load modulation communicating with a contactless reader, according to one embodiment;

FIG. 2 schematically shows the operation of a clock signal extraction circuit and of a circuit for modifying the value of the threshold of the extraction circuit in a device of contactless communication by active load modulation, according to one embodiment;

FIG. 3 schematically shows a first example of embodiment of a clock signal extraction circuit and of a circuit for modifying the value of the threshold of the extraction circuit, according to one embodiment;

FIG. 4 schematically shows a second example of embodiment of a clock signal extraction circuit and of a circuit for modifying the value of the threshold of the extraction circuit, according to one embodiment;

FIG. 5 schematically shows a variant of the second example of embodiment of a clock signal extraction circuit and of a circuit for modifying the value of the threshold of the extraction circuit, according to one embodiment.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for the understanding of the described embodiments have been illustrated and described in detail. In particular, the forming of the different elements and circuits (matching circuit, phase-locked loop, digital conversion circuit, transmission circuit, etc.) of the device is not described in detail. Those skilled in the art will be capable of implementing in detailed fashion the different functions of the device based on the functional description given herein.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

Unless specified otherwise, the expressions “about,” “approximately,” “substantially,” and “in the order of” signify plus or minus 10%, preferably of plus or minus 5%.

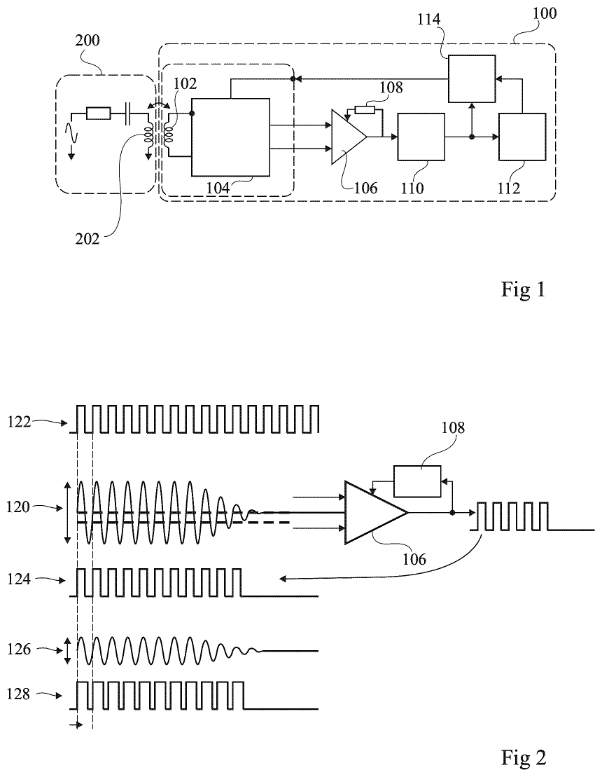

An example of a device 100 of contactless communication by active load modulation according to a specific embodiment is described hereafter in relation with FIG. 1.

Device 100 is of NFC type, that is, is configured to use a communication protocol compatible with the NFC technology. In the described example, device 100 corresponds to a device in card emulation (CE) mode. In FIG. 1, device 100 is shown during a communication with a NFC-type contactless reader 200.

In the described example of embodiment, device 100 and reader 200 communicate with each other by using an OOK-type modulation. Thus, the electromagnetic field emitted by reader 200 and received by device 100 is made to switch state, and to be either in a high state, transmitted in the form of a sinusoidal signal for example having a frequency equal to 13.56 MHz (carrier frequency), or in a low state transmitted in the form of a zero signal.

In the described example of embodiment, device 100 includes an antenna 102 intended to exchange data with an antenna 202 of reader 200 via the emission of electromagnetic fields by these antennas 102, 202 and the magnetic coupling between these antennas 102, 202.

In the specific configuration shown in FIG. 1, device 100 further includes a matching circuit 104 electrically coupling antenna 102 to the other elements of device 100. Circuit 104 may include passive components, and may especially be used to match the impedance of antenna 102 to interface the input and output signals of antenna 102.

Device 100 further includes a clock signal extraction circuit 106 configured in particular to receive as an input a reception signal originating from a magnetic field intended to be received by antenna 102 and to be output by matching circuit 104. Circuit 106 is also configured to output a clock signal having a first value, for example “1” or high state, when the reception signal is higher than a value of a threshold of circuit 106 and having a second value, for example “0” or low state, when the reception signal is lower than the value of the threshold of circuit 106. In this example, circuit 106 thus forms a comparator outputting a clock signal extracted from the reception signal applied to its input.

In the described example, when the signal received by antenna 102 corresponds to a high state transmitted in the form of a sinusoidal signal, the value of the clock signal output by circuit 106 alternates between the first and second values at a frequency equal to the frequency of the sinusoidal signal for the entire duration of the high state. When the signal received by antenna 102 corresponds to a low state transmitted in the form of a zero signal, the value of the clock signal output by circuit 106 is also zero for the entire duration of this low state.

Device 100 also includes a circuit 108 for modifying the value of the threshold of circuit 106, configured to decrease the value of the threshold when the value of the clock signal output by circuit 106 is equal to the first value, or to increase the value of the threshold when the value of the clock signal is equal to the second value. In the example of FIG. 1, an input of circuit 108 is electrically coupled to the output of circuit 106, and an output of circuit 108 is electrically coupled to an input of circuit 106.

In the described example of embodiment, device 100 further includes a phase-locked loop 110, or PLL, having an input electrically coupled to the output of circuit 106. PLL 110 is intended to receive as an input the clock signal transmitted at the output of circuit 106 and to output a signal synchronized and in phase with the clock signal received on its input.

Device 100 may also include a digital conversion circuit 112 including an input electrically coupled to an output of PLL 110. Circuit 112 is particularly intended to decode the signal transmitted by reader 200.

In the described example of embodiment, device 100 further includes a transmission circuit 114 including an output electrically coupled to antenna 102 and on which a modulation signal intended to be transmitted by antenna 102 and in phase with the reception signal is intended to be delivered. Circuit 114 may further include a first input electrically coupled to an output of PLL 110 and a second input electrically coupled to an output of digital conversion circuit 112.

In the diagram of FIG. 1, only some of the elements of device 100 are shown. Device 100 includes, in addition to those visible in FIG. 1, other circuits and elements not described herein.

The operation of an example of embodiment of circuit 106 and of circuit 108 for modifying the value of the threshold of circuit 106 is described hereafter in relation with FIG. 2.

Reference numeral 120 designates a first example of a reception signal received as an input of circuit 106. This first example of reception signal may be obtained when the antennas of reader 200 and of device 100 are close and strongly coupled to each other, and for example has a peak-to-peak amplitude in the order of 1 V.

Reference numeral 122 designates a square signal representing the clock signal used by reader 200 for data transmission. The phase and the frequency of signal 120 are thus similar to those of signal 122 which have been used to obtain the non-modulated electromagnetic field emitted by reader 200.

In the example of embodiment described in relation with FIG. 2, circuit 106 is configured such that the clock signal output by circuit 106 is at state “1,” or high state, when the reception signal is higher than the threshold of circuit 106 (having a value equal to 0 V in this example), and is at state “0,” or low state, when the reception signal is lower than the threshold of circuit 106. Further, in this example of embodiment, circuit 108 is configured to decrease the value of the threshold of circuit 106 when the clock signal output by circuit 106 is at state “1.” For example, the decreased value of the threshold may be in the range from 10% to 20% of the minimum amplitude of the reception signal (which is for example in the order of 0.2 V).

Reference numeral 124 designates the clock signal obtained at the output of circuit 106 when reception signal 120 is applied at the input of circuit 106.

In this example, due to the fact that the value of the threshold of circuit 106 is equal to 0 when the clock signal delivered by circuit 106 is at state “0,” the switching from state “0” to state “1” of clock signal 124 occurs at the same time as the switching from a negative value to a positive value of reception signal 120. However, due to the fact that the value of the threshold of circuit 106 is decreased when the clock signal delivered by circuit 106 is at state “1,” the switching from state “1” to state “0” of clock signal 124 occurs with a delay with respect to the switching from a positive value to a negative value of reception signal 120. When the peak-to-peak amplitude of signal 120 is significant (as is here the case), this delay is very short.

Reference numeral 126 designates a second example of a reception signal received as an input of circuit 106. This second example of reception signal can be obtained when the antennas of reader 200 and of device 100 are distant and lightly coupled to each other, and for example has a peak-to-peak amplitude in the order of 0.2 V.

Reference numeral 128 designates the clock signal obtained at the output of circuit 106 when reception signal 126 is applied at the input of circuit 106.

Since, when reception signal 126 is applied at the input of circuit 106, the switching from state “0” to state “1” of signal 128 occurs at the same time as the switching from a negative value to a positive value of signal 126, and the switching from state “1” to state “0” of signal 128 occurs with a delay with respect to the switching from a positive value to a negative value of signal 126. Due to the fact that the peak-to-peak amplitude of signal 126 is low, this delay is more significant than in the case of a reception signal of high peak-to-peak amplitude such as signal 120. In FIG. 2, this more significant delay results in a state “1” of signal 128 of longer duration at each period of signal 128.

Whether the amplitude of the reception signal is strong or light, the lowering of the threshold of circuit 106 achieved by circuit 108 when the clock signal delivered by circuit 106 is at state “1” enables to avoid having, in the clock signal delivered by circuit 106, the occurrence of parasitic variations or switchings, or jitter, for example corresponding to self-oscillations, when the information transmitted by the reception signal is in the low state, which parasitic variations may be generated due to the glitches, or faults, generated by the noise in the reception signal, this time in the absence of circuit 108. In FIG. 2, parasitic transient phenomena correspond to the attenuation occurring on the reception signal due to the fact that the switching from the high state to the low state of the information transmitted on the reception signal is not instantaneous. This lowering of the threshold of circuit 106 performed by circuit 108 when the clock signal is at state “1” enables to also avoid parasitic switchings of the clock signal delivered by circuit 106 when noise is present in the reception signal, for example when its value is close to 0.

Further, due to the fact that the value of the threshold is unchanged when the clock signal is at state “0,” the switching from state “0” to state “1” of the clock signal obtained at the output of circuit 106 occurs with no delay with respect to the switching from a negative value to a positive value of the reception signal. Thus, when PLL 110 is synchronized with respect to the rising edges of the signal applied to its input (which corresponds to the clock signal output by circuit 106), this lack of delay enables to eventually have a response signal of device 100 which is in phase with the electromagnetic field emitted by reader 200. Further, the delay obtained in the output clock signal of circuit 106 during the switching from a positive value to a negative value of the reception signal has no impact when PLL 110 is synchronized with respect to the rising edges of the clock signal.

In the above examples, circuit 108 is configured to decrease the value of the threshold of circuit 106 when the clock signal is at state “1.” In this case, when the clock signal is at state “0,” circuit 108 does not modify the value of the threshold of circuit 106 which operates at its nominal accuracy, which enables not to degrade the intrinsic phase shift of device 100. In this example, only the falling edges of the clock signal are affected by a phase shift, which has no incidence when PLL 110 is synchronized with respect to the rising edges of the clock signal.

According to another example, for example when PLL 110 is synchronized with respect to the falling edges of the clock signal, circuit 108 may be configured to increase the value of the threshold of circuit 106 when the clock signal is at state “0.” In this case, when the clock signal is at state “1,, circuit 108 does not modify the value of the threshold of circuit 106 which operates at its nominal accuracy (value of the threshold for example equal to 0 V), which enables not to degrade the intrinsic phase shift of device 100. In this case, only the rising edges of the clock signal are affected by a phase shift, which has no incidence when PLL 110 is synchronized with respect to the falling edges of the clock signal.

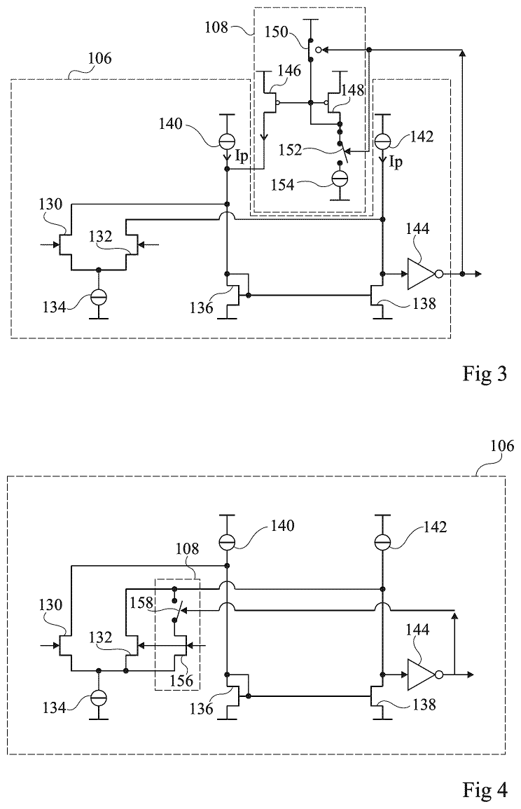

A first example of embodiment of circuit 106 and of circuit 108 is described hereabove in relation with FIG. 3.

In this first example, circuit 106 includes a differential pair formed of two first transistors 130, 132, each including a first one of their source/drain electrodes electrically coupled to a first current source 134. In the example of FIG. 3, first transistors 130, 132 are for example NMOS transistors and their first source/drain electrode corresponds to the source electrode. In this first example, the reception signal received as an input of circuit 106 is applied to the gate of transistor 130, and the signal opposite to the reception signal is applied to the gate of transistor 132.

The circuit 106 according to this first example further includes a first current mirror including two second transistors 136, 138, each including a first one of their source/drain electrodes electrically coupled to a second one of the source/drain electrodes of the two first transistors 130, 132. In the example of FIG. 3, second transistors 136, 138 are for example NMOS transistors and their first source/drain electrode corresponds to the drain electrode, and the second ones of the source/drain electrodes of first transistors 130, 132 correspond to the drain electrodes. The first one of the source/drain electrodes of second transistor 136 is also coupled to the gate of second transistor 136. The first ones of the source/drain electrodes of second transistors 136, 138 are also electrically coupled to second current sources 140, 142 ensuring the biasing of this first current mirror and supplying the current for the proper biasing of the differential pair formed by the two first transistors 130, 132.

The circuit 106 according to this first example further includes a high-gain amplifier 144 having its input electrically coupled to the first source/drain electrode of transistor 138, and having its output forming the output of circuit 106 on which the clock signal is intended to be delivered. Amplifier 144 may operate in saturation so that the obtained clock signal corresponds to a square signal.

The differential pair formed by the two first transistors 130, 132 enables to convert the potential difference applied to the gates of transistors 130, 132 into a current difference appearing at the junction of the input of amplifier 144 with one of the branches of the first current mirror formed by the two second transistors 136, 138 (that including transistor 138 in FIG. 3). The use of the first current mirror thus enables to deliver at the input of amplifier 144 a voltage having a value proportional to this current difference. Finally, amplifier 144, which has a high gain and which operates in saturation, enables to convert the voltage applied on its input into a square signal (clock signal at state “1” when the input voltage of amplifier 144 is positive, and at state “0” when the input voltage of amplifier 144 is negative).

Circuit 108 may be configured to unbalance a biasing of the first current mirror formed by second transistors 136, 138.

In this first example, circuit 108 includes third transistors 146, 148 forming a second current mirror electrically coupled to one of the branches of the first current mirror formed by second transistors 136, 138. In the example of FIG. 3, the third transistors 146, 148 are for example PMOS transistors.

The circuit 108 according to this first example also includes a first switch 150 configured to electrically couple or not the electric power supply potential of device 100 to the gates of the third transistors 146, 148 forming the second current mirror, and a second switch 152 configured to electrically couple or not the second current mirror to the reference electric potential of device 100 via a third current source 154.

In this first example, circuits 106 and 108 may be electrically powered between a first electric potential V1 (applied to first switch 150, third transistors 146, 148, and second current sources 140, 142) and a second electric potential V2 (applied to third current source 154, second transistors 136, 138, and first current source 134). By selecting these electric potentials such that V1=−V2, the common-mode voltage, corresponding to the midpoint of the amplifier, is zero. More generally, common-mode voltage Vmc can be expressed by the equation:

$$V mc = ( V 1 + V2 ) / 2 \qquad Math 1$$

In the example shown in FIG. 3, first switch 150 is in the off state when the clock signal delivered by circuit 106 and applied to its control input is at state “1,” and is in the on state when the clock signal is at state “0.” However, second switch 152 is in the off state when the clock signal applied to its control input is at state “0,” and is in the on state when the clock signal is at state “1”.

Thus, when the clock signal is at state “0,” circuit 108 has no impact on the value of the threshold of circuit 106 (circuit 106 operates as if circuit 108 was absent). No current flows through the current mirror of the circuit 108 shown in FIG. 3.

When the clock signal is at state “1,” the connection of circuit 108 to one of the branches of the first current mirror formed by second transistors 136, 138 modifies the value of the threshold of circuit 106. Indeed, when first switch 150 is in the off state and second switch 152 is in the on state, the electrical coupling of circuit 108 to one of the branches of the first current mirror adds an additional current in this branch with respect to the other branch of the first current mirror. This current dissymmetry in the branches of the first current mirror is then also present at the junction between the input of amplifier 144 and one of the branches of the differential pair, which generates an offset, or shift, of the value of the threshold of circuit 106.

The voltage at the input of amplifier 144 is proportional to the current differences (i140−i130)−(i142−i132), with i130, i140, i132 and i142 corresponding to the currents flowing through components 130, 140, 132, and 142 respectively. Thus, the modification of the threshold voltage of circuit 106 is obtained due to the current difference between the source formed by current source 140+circuit 108 and source 142.

When circuit 108 is inactive (first switch 150 in the on state), the bias current flowing through the drain of second transistor 136 is equal to the current supplied by current source 140 from which is subtracted the bias current flowing through transistor 130, and which is then equal to the current supplied by current source 142 from which is subtracted the bias current flowing through transistor 132. The threshold voltage of circuit 106 is then not modified.

When circuit 108 is active (first switch 150 in the off state), the bias current flowing through the drain of second transistor 136 is equal to the current supplied by current source 140 from which is subtracted the bias current flowing through transistor 130, and to which is added the current supplied circuit 108. The current supplied by current source 140 is in this case no longer equal to that supplied by current source 142 from which is subtracted the bias current flowing through transistor 132, which generates the modification of the threshold voltage of circuit 106.

As a variant, the circuit 108 according to this first example may be configured to increase the value of the threshold of circuit 106 when the clock signal is at state “0,” and not to modify the value of the threshold of circuit 106 when the clock signal is at state “1.” The circuit 108 according to this variant for example includes the same elements as those shown in FIG. 3, except for first switch 150, which is in this case configured to be in the on state when the clock signal applied to its control input is at state “1,” and to be in the off state when the clock signal is at state “0.” In this variant, second switch 152 is also configured so that it is in the on state when the clock signal applied to its control input is at state “0,” and in the off state when the clock signal is at state “1.” Further, in this variant, as compared with the example previously described in relation with FIG. 3, the output of circuit 108 is not electrically coupled to the branch of the first current mirror formed by transistor 136 but is electrically coupled to the output branch of the first current mirror formed by transistor 138, and thus to the input of amplifier 144.

A second example of embodiment of circuit 106 and of circuit 108 is described hereafter in relation with FIG. 4.

In this second example, circuit 106 includes the same components as those of the previously described circuit 106 of the first example of embodiment.

The circuit 108 according to this second example includes a fourth transistor 156 and a switch 158 configured to electrically couple or not the fourth transistor 156 in parallel with the transistor 132 of circuit 106. More particularly, in this example, switch 158 is configured to be in the off state when the clock signal is at state “0,” and to be in the on state when the clock signal is at state “1.”

In this second example, an unbalancing of one of the branches of the differential pair is performed by the connection of fourth transistor 156 in parallel with transistor 132, increasing the transconductance of the transistor seen for this branch of the differential pair, and modifying the value of the threshold of circuit 106.

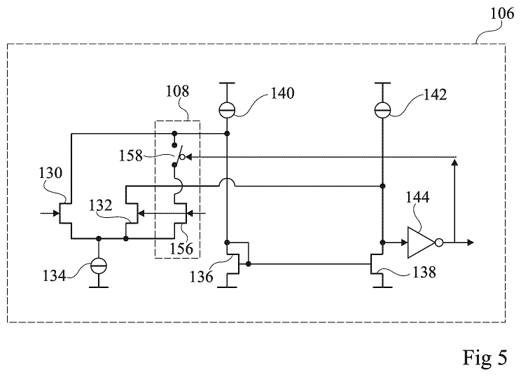

As a variant, the circuit 108 according to this second example may be configured to increase the value of the threshold of circuit 106 when the clock signal is at state “0,” and not to modify the value of the threshold of circuit 106 when the clock signal is at state “1.” The circuit 108 according to this variant for example includes the same elements as those shown in FIG. 4, except for the fourth transistor 156 and for switch 158, which is configured to electrically couple or not the fourth transistor 156 in parallel with the transistor 130 of circuit 106, switch 158 being configured to be in the on state when the clock signal applied to its control input is at state “0,” and to be in the off state when the clock signal is at state “1.” Such a variant of circuits 106 and 108 is shown in FIG. 5.

In the example of circuit 106 described hereabove in relation with FIGS. 3 to 5, it is possible to modify the value of the threshold of circuit 106 by modifying the values of the currents delivered by each of current sources 140, 142. Thus, when the currents delivered by sources 140, 142 are equal, the value of the nominal threshold (that is, with no intervention of circuit 108) of circuit 106 may be equal to 0. When the current delivered by source 140 is greater than that delivered by source 142, the value of the nominal threshold of circuit 106 may be smaller than 0. When the current delivered by source 140 is smaller than that delivered by source 142, the value of the nominal threshold of circuit 106 may be greater than 0.

In the different previously-described examples, circuit 108 and circuit 106 may be seen as forming together a dynamic threshold comparator, where a variation of the threshold is only present when the output signal of the comparator is in the high or low state.

In the previously-described examples of FIGS. 3 and 4, each of the source/drain electrodes of one of the transistors may correspond to the source electrode or to the drain electrode of this transistor, according to the type, or to the conductivity, n or p, of the transistor.

Further, one or a plurality of different components of circuit 106 and/or of circuit 108 described hereabove may be used to perform functions similar to those described.

In the different previously-described examples of embodiment, each of switches 150, 152, 158 may correspond to a MOS transistor.

In the different examples of embodiment, the state “1” of a signal may correspond to an amplitude equal to the power supply voltage of device 100, and the state “0” of a signal may correspond to an amplitude equal to the reference potential of device 100, for example the ground, which has a zero electric potential.

In the above description, device 100 corresponds to a device of contactless communication by active load modulation which is, during a communication with a reader, in card emulation mode. Device 100 may be provided with functionalities other than those described hereabove. Device 100 may for example correspond to a cell phone or a connected object such as a watch.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

In one embodiment, a device (100) of contactless communication by active load modulation, includes at least: a clock signal extraction circuit (106) configured to receive as an input a reception signal and to output a clock signal having a first value when the reception signal is greater than a threshold of the clock signal extraction circuit (106) and having a second value when the reception signal is smaller than the threshold; a circuit (108) for modifying the value of the threshold, configured to decrease the value of the threshold when the value of the clock signal is equal to the first value, or to increase the value of the threshold when the value of the clock signal is equal to the second value.

In one embodiment, the threshold of the clock signal extraction circuit (106) has a zero value.

In one embodiment, the clock signal extraction circuit (106) and the circuit (108) for modifying the value of the threshold are configured so that the decreased value of the threshold is in the range from 10% to 20% of a minimum amplitude of the reception signal.

In one embodiment, the clock signal extraction circuit (106) includes a differential pair (130, 132).

In one embodiment, the clock signal extraction circuit (106) further includes a first current mirror (136, 138) electrically coupled in parallel with the differential pair (130, 132).

In one embodiment, the circuit (108) for modifying the value of the threshold is configured to unbalance a biasing of the first current mirror (136, 138) of the clock signal extraction circuit (106) or a biasing of the differential pair (130, 132) and of the first current mirror (136, 138) of the clock signal extraction circuit (106).

In one embodiment, the clock signal extraction circuit (106) may further include an amplifier (144) having an input electrically coupled to one of the branches of the first current mirror (136, 138).

In one embodiment, the circuit (108) for modifying the value of the threshold may include a second current mirror (146, 148) electrically coupled to one of the branches of the first current mirror (136, 138) and switches (150, 152) configured to electrically couple the second current mirror (146, 148) to an electric power supply potential of the device (100) and to a current source, itself coupled to a reference electric potential of the device (100), according to the value of the clock signal.

In one embodiment, the circuit (108) for modifying the value of the threshold may include a transistor (156) and a switch (158) configured to electrically couple the transistor (156) of the circuit (108) for modifying the value of the threshold in parallel with a transistor (130) of the differential pair (130, 132) when the value of the clock signal is equal to the first value or to the second value.

In one embodiment, the device (100) further includes a phase-locked loop (110) having an input electrically coupled to an output of the clock signal extraction circuit (106).

In one embodiment, the device (100) further includes: a digital conversion circuit (112) including an input electrically coupled to an output of the phase-locked loop (110); a transmission circuit (114) including an output electrically coupled to the antenna (102) and on which a modulation signal in phase with the reception signal is intended to be delivered, and including a first input electrically coupled to an output of the phase-locked loop (110) and a second input electrically coupled to an output of the digital conversion circuit (112).

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A device of contactless communication by active load modulation, comprising:
a clock signal extraction circuit configured to receive as an input a reception signal and to output a clock signal having a first value when the reception signal is greater than a threshold of the clock signal extraction circuit and having a second value when the reception signal is smaller than the threshold; and
a circuit for modifying the value of the threshold, configured to decrease the value of the threshold when the value of the clock signal is equal to the first value, or to increase the value of the threshold when the value of the clock signal is equal to the second value.

2. The device according to claim 1, wherein the threshold of the clock signal extraction circuit has a zero value.

3. The device according to claim 1, wherein the clock signal extraction circuit and the circuit for modifying the value of the threshold are configured so that the decreased value of the threshold is in the range from 10% to 20% of a minimum amplitude of the reception signal.

4. The device according to claim 1, wherein the clock signal extraction circuit comprises a differential pair.

5. The device according to claim 4, wherein the clock signal extraction circuit further comprises a first current mirror electrically coupled in parallel with the differential pair.

6. The device according to claim 5, wherein the circuit for modifying the value of the threshold is configured to unbalance a biasing of the first current mirror of the clock signal extraction circuit or a biasing of the differential pair and of the first current mirror of the clock signal extraction circuit.

7. The device according to claim 5, wherein the clock signal extraction circuit further comprises an amplifier having an input electrically coupled to one of the branches of the first current mirror.

8. The device according to claim 4, wherein the circuit for modifying the value of the threshold comprises a second current mirror electrically coupled to one of the branches of the first current mirror and switches configured to electrically couple the second current mirror to an electric power supply potential of the device and to a current source, itself coupled to a reference electric potential of the device, according to the value of the clock signal.

9. The device according to claim 4, wherein the circuit for modifying the value of the threshold comprises a transistor and a switch configured to electrically couple the transistor of the circuit for modifying the value of the threshold in parallel with a transistor of the differential pair when the value of the clock signal is equal to the first value or to the second value.

10. The device according to claim 1, further comprising a phase-locked loop having an input electrically coupled to an output of the clock signal extraction circuit.

11. The device according to claim 10, further comprising:
a digital conversion circuit including an input electrically coupled to an output of the phase-locked loop; and
a transmission circuit including an output electrically coupled to the antenna and on which a modulation signal in phase with the reception signal is intended to be delivered, and including a first input electrically coupled to an output of the phase-locked loop and a second input electrically coupled to an output of the digital conversion circuit.

12. A method, comprising:
receiving a reception signal at a clock signal extraction circuit;
outputting, from the clock signal extraction circuit, a clock signal having a first value when the reception signal is greater than a threshold of the clock signal extraction circuit and having a second value when the reception signal is smaller than the threshold; and
modifying, with a circuit, the threshold by decreasing the threshold when the value of the clock signal is equal to the first value and increasing the threshold when the value of the clock signal is equal to the second value.

13. The method of claim 12, wherein the threshold of the clock signal extraction circuit has a zero value.

14. The device according to claim 12, comprising decreasing the threshold in a range from 10% to 20% of a minimum amplitude of the reception signal.

15. The method of claim 12, wherein the clock signal extraction circuit comprises a differential pair.

16. The method of claim 15, wherein the clock signal extraction circuit further comprises a first current mirror electrically coupled in parallel with the differential pair.

17. The method claim 16, comprising unbalancing a biasing the first current mirror of the clock signal extraction circuit.

18. A device, comprising:
a clock extraction circuit including:
a differential input coupled to receive a reception signal from the matching circuit;
a feedback input; and
an output configured to provide a clock signal based on the reception signal and an internal threshold; and
a feedback circuit having an input coupled to receive the clock signal and an output coupled to the feedback input of the clock extraction circuit.

19. The device of claim 18, wherein the feedback circuit is configured to adjust the internal threshold.

20. The device of claim 18, comprising:
an antenna; and
a matching circuit having an input coupled to the antenna and an output coupled to provide the reception signal to the clock extraction circuit.
